(19) United States
(12) Patent Application Publication
(10) Pub. No.: US 2014/0029078 A1
(43) Pub. Date: Jan. 30, 2014

(54) DEVICES AND METHODS FOR PROTECTING ELECTROMECHANICAL DEVICE ARRAYS

(71) Applicants: Leonard Eugene Fennell, Foster City, CA (US); Tsongming Kao, Sunnyvale, CA (US); Teruo Sasagawa, Los Gatos, CA (US); Sapna Patel, Fremont, CA (US); Hung-Jen Wang, New Taipei City (TW)

(72) Inventors: Leonard Eugene Fennell, Foster City, CA (US); Tsongming Kao, Sunnyvale, CA (US); Teruo Sasagawa, Los Gatos, CA (US); Sapna Patel, Fremont, CA (US); Hung-Jen Wang, New Taipei City (TW)

(73) Assignee: QUALCOMM MEMS TECHNOLOGIES, INC., San Diego, CA (US)

(21) Appl. No.: 13/557,061

(22) Filed: Jul. 24, 2012

(51) Int. Cl. G02B 26/00; H05K 3/00; H05K 7/00

(52) U.S. Cl. 359/238; 361/679.01; 29/846

(57) ABSTRACT

This disclosure provides systems, methods and apparatus for protecting electromechanical systems (EMS) devices from mechanical interference. In one aspect, an array of EMS devices may include one or more regions in which an EMS device is replaced with a spacer structure, such that the overall height of the spacer structure is greater than the height of the surrounding EMS devices. In another aspect, resilient spacer structures can be formed overlying stable portions of an EMS device array. These resilient spacer structures may be formed from a cross-linked organic material.

### TECHNICAL FIELD

This disclosure relates to methods and devices for protecting arrays of electromechanical systems (EMS) devices from mechanical interference.

### DESCRIPTION OF THE RELATED TECHNOLOGY

EMS include devices having electrical and mechanical elements, actuators, transducers, sensors, optical components such as mirrors and optical films, and electronics. EMS devices or elements can be manufactured at a variety of scales including, but not limited to, microscales and nanoscales. For example, microelectromechanical systems (MEMS) devices can include structures having sizes ranging from about a micron to hundreds of microns or more. Nanoelectromechanical systems (NEMS) devices can include structures having sizes smaller than a micron including, for example, sizes smaller than several hundred nanometers. Electromechanical elements may be created using deposition, etching, lithography, and/or other micromachining processes that etch away parts of substrates and/or deposited material layers, or that add layers to form electrical and electromechanical devices.

One type of EMS device is called an interferometric modulator (IMOD). The term IMOD or interferometric light modulator refers to a device that selectively absorbs and/or reflects light using the principles of optical interference. In some implementations, an IMOD display element may include a pair of conductive plates, one or both of which may be transparent and/or reflective, wholly or in part, and capable of relative motion upon application of an appropriate electrical signal. For example, one plate may include a stationary layer deposited over, on or supported by a substrate and the other plate may include a reflective membrane separated from the stationary layer by an air gap. The position of one plate in relation to another can change the optical interference of light incident on the IMOD display element. IMOD-based display devices have a wide range of applications, and are anticipated to be used in improving existing products and creating new products, especially those with display capabilities.

EMS devices such as IMOD devices are susceptible to mechanical and environmental damage, and may be protected from such damage by packaging the EMS devices using a backplate sealed to a substrate supporting the EMS devices. However, as the package thickness decreases, a risk of mechanical interference from flexure of the backplate increases. Additional device components may be incorporated into the package in order to protect the EMS devices from mechanical interference from a backplate.

### SUMMARY

The systems, methods and devices of this disclosure each have several innovative aspects, no single one of which is solely responsible for the desirable attributes disclosed herein.

One innovative aspect of the subject matter described in this disclosure can be implemented in a device, including a conductive layer supported by an underlying substrate, a movable layer overlying at least a portion of the conductive layer, a plurality of support structures underlying at least a portion of the movable layer and spacing the movable layer apart from the conductive layer by a cavity, where the plurality of post structures are anchored to an underlying layer at anchor locations, and a spacer layer disposed in an area between anchor locations, where the spacer structure underlies a first layer including the same material as the support structures and a second layer including the same material as the movable layer, where the upper surface of the second layer overlying the spacer layer is located at a greater height from the surface of the substrate than the remainder of the device.

In some implementations, the conductive layer can be conductive absorber layer. In some implementations, the device can additional include a masking structure extending underneath at least the anchor locations and the spacer layer. In some further implementations, the masking structure can include an interferometric black mask.

In some implementations, the first layer can extend between at least a first anchor location and a second anchor location. In some further implementations, the first layer can extend between four adjacent anchor locations.

In some implementations, the device can additionally include an additional spacer structure overlying a portion of the device, where the additional spacer structure includes an organic material. In some further implementations, the additional spacer structure can overlie a support structure, and where the additional spacer structure does not extend outward beyond the edges of the anchor location underlying the support structure. In some further implementations, the additional spacer structure can overlie the spacer layer, and where the additional spacer structure does not extend outward beyond the edges of the spacer layer.

Another innovative aspect of the subject matter described in this disclosure can be implemented in a device, including an array of interferometric modulators (IMODs) arranged as a plurality of pixels, where the array includes a first portion of the array defining a first pixel, the first pixel including a plurality of IMODs configured to reflect light of a first color, and a plurality of IMODs configured to reflect light of a second color, and a second portion of the array defining a second pixel, where the second portion of the array is substantially similar in size to the first portion of the array, the second pixel including at least one less IMOD configured to reflect light of a first color than the first pixel, where the second pixel further includes a spacer disposed within the second portion of the array, and where the spacer extends to a height higher than the remainder of the second pixel.

In some implementations, the first color of light can be blue and the second color of light can be red, where the first pixel further includes a plurality of IMODs configured to reflect green light. In some implementations, the device can additionally include an interferometric black mask underlying at least a portion of the spacer. In some implementations, the device can include an oxide.

Another innovative aspect of the subject matter described in this disclosure can be implemented in a method of fabricating a device, including forming at least one spacer over a substrate, forming a sacrificial layer over the spacer, patterning the sacrificial layer to include a plurality of apertures, where at least one of the plurality of apertures extends over the spacer, forming a support layer over the patterned sacrificial layer, and patterning the support layer to form support structures, where a portion of the support layer overlying the spacer remains in place.

In some implementations, the method can additionally include forming a movable layer after patterning the support layer to form support structures, and patterning the movable layer, where a portion of the movable layer overlying the spacer remains in place.

In some implementations, the method can additionally include forming a conductive layer over the substrate prior to forming the sacrificial layer. In some further implementations, the method can additionally include forming a buffer layer over at least the conductive layer and the spacer. In some further implementations, the method can additionally include forming an interferometric black mask over the substrate, where the interferometric black mask is formed over the masking structure.

Another innovative aspect of the subject matter described in this disclosure can be implemented in a device, including a conductive layer supported by an underlying substrate, a movable layer overlying at least a portion of the conductive layer, a plurality of support structures underlying at least a portion of the movable layer and spacing the movable layer apart from the conductive layer by a cavity, where the plurality of post structures are anchored to an underlying layer at anchor locations, and means for raising the height of overlying layers, where the raising means underlies a first layer including the same material as the support structures and a second layer including the same material as the mechanical layer, where the upper surface of the second layer overlying the raising means is located at a greater height from the surface of the substrate than the remainder of the device.

In some implementations, the raising means can include a spacer layer disposed in an area between anchor locations.

Another innovative aspect of the subject matter described in this disclosure can be implemented in a device, including a conductive layer supported by an underlying substrate, a movable layer overlying at least a portion of the conductive layer, a plurality of support structures underlying at least a portion of the mechanical layer and spacing the movable layer apart from the conductive layer by a cavity, where the plurality of post structures are anchored to an underlying layer at anchor locations, and a spacer overlying at least one support structure, where the spacer includes an organic material, and where a base of the spacer does not extend outward beyond the edges of the anchor location underlying the support structure.

In some implementations, the spacer can include a cross-linked organic material. In some implementations, the conductive layer can include an optical absorber, and at least a portion of the movable layer adjacent the cavity can include a reflective material.

Details of one or more implementations of the subject matter described in this disclosure are set forth in the accompanying drawings and the description below. Although the examples provided in this disclosure are primarily described in terms of EMS and MEMS-based displays the concepts provided herein may apply to other types of displays such as liquid crystal displays, organic light-emitting diode (“OLED”) displays, and field emission displays. Other features, aspects, and advantages will become apparent from the description, the drawings and the claims. Note that the relative dimensions of the following figures may not be drawn to scale.

### BRIEF DESCRIPTION OF THE DRAWINGS

FIG. 1 is an isometric view illustration depicting two adjacent interferometric modulator (IMOD) display elements in a series or array of display elements of an IMOD display device.

FIG. 2 is a system block diagram illustrating an electronic device incorporating an IMOD-based display including a three element by three element array of IMOD display elements.

FIG. 3 is a flow diagram illustrating a manufacturing process for an IMOD display or display element.

FIGS. 4A-4E are cross-sectional illustrations of various stages in a process of making an IMOD display or display element.

FIGS. 5A and 5B are schematic exploded partial perspective views of a portion of an electromechanical systems (EMS) package including an array of EMS elements and a backplate.

FIG. 6A shows an example of a schematic illustration of an interferometric modulator pixel.

FIG. 6B shows an example of a schematic illustration of an interferometric modulator pixel in which one of the subpixels has been replaced with a spacer structure.

FIG. 6C is a perspective view schematically illustrating an array of interferometric modulators disposed on a substrate in which at least one subpixel has been replaced by a spacer structure.

FIGS. 7A-7E show an example of a fabrication process which can be used to form a spacer structure within an array of interferometric modulators.

FIG. 8 shows an example of a cross-section of another implementation of spacer structure within an array of interferometric modulators.

FIG. 9 shows an example of a block diagram illustrating a method of fabricating an array of interferometric modulators including at least one spacer structure disposed within the array.

FIG. 10 shows an example of a cross-section of a portion of an array of interferometric modulators in which a spacer structure overlies a portion of a support structure.

FIGS. 11A-11D show an example of a fabrication process which can be used to form an overlying spacer structure within an array of interferometric modulators.

FIG. 12 shows an example of a block diagram illustrating a method of fabricating an array of interferometric modulators including at least one spacer overlying a support structure.

FIG. 13 shows an example of an interferometric modulator array which includes both a spacer structure which replaces a subpixel of the array and an additional spacer structure overlying the subpixel-replacing spacer structure.

FIGS. 14A and 14B are system block diagrams illustrating a display device that includes a plurality of IMOD display elements.

Like reference numbers and designations in the various drawings indicate like elements.

### DETAILED DESCRIPTION

The following description is directed to certain implementations for the purposes of describing the innovative aspects of this disclosure. However, a person having ordinary skill in the art will readily recognize that the teachings herein can be applied in a multitude of different ways. The described implementations may be implemented in any device, apparatus, or system that can be configured to display an image, whether in motion (such as video) or stationary (such as still images), and whether textual, graphical or pictorial. More particularly, it is contemplated that the described implementations may be included in or associated with a variety of electronic devices such as, but not limited to: mobile telephones, multimedia Internet enabled cellular telephones, mobile television receivers, wireless devices, smartphones, Bluetooth® devices, personal data assistants (PDAs), wireless electronic mail receivers, hand-held or portable computers, netbooks, notebooks, smartbooks, tablets, printers, copiers, scanners, facsimile devices, global positioning system (GPS) receivers/navigators, cameras, digital media players (such as MP3 players), camcorders, game consoles, wrist watches, clocks, calculators, television monitors, flat panel displays, electronic reading devices (e.g., e-readers), computer monitors, auto displays (including odometer and speedometer displays, etc.), cockpit controls and/or displays, camera view displays (such as the display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, washers, dryers, washer/dryers, parking meters, packaging (such as in electromechanical systems (EMS) applications including microelectromechanical systems (MEMS) applications, as well as non-EMS applications), aesthetic structures (such as display of images on a piece of jewelry or clothing) and a variety of EMS devices. The teachings herein also can be used in non-display applications such as, but not limited to, electronic switching devices, radio frequency filters, sensors, accelerometers, gyroscopes, motion-sensing devices, magnetometers, inertial components for consumer electronics, parts of consumer electronics products, varactors, liquid crystal devices, electrophoretic devices, drive schemes, manufacturing processes and electronic test equipment. Thus, the teachings are not intended to be limited to the implementations depicted solely in the Figures, but instead have wide applicability as will be readily apparent to one having ordinary skill in the art.

Because some EMS devices, such as interferometric modulators (IMODs), may be monolithically fabricated on a supporting substrate, additional protection from mechanical and environmental interference may be provided via an overlying protective backplate which forms part of an EMS device package. Even with a backplate in place, however, flexure of the backplate between supports can bring the backplate into contact with the EMS devices unless sufficient support for the backplate and/or spacing between the backplate and the EMS devices is provided. By dispersing spacers throughout an array of EMS devices, the necessary spacing between the backplate and the EMS devices can be reduced, and the thickness of the EMS device package can be reduced. In some devices, the spacers may be provided within an EMS device array without reducing the fill factor of the EMS devices by disposing spacers on top of EMS device elements, such as support structures. However, as the size of the EMS devices is reduced, and the density of the devices within an array increases, increased reliability of such spacers is needed, or an alternative placement of such spacers. In some devices, EMS devices of a certain type, such as blue subpixels in an interferometric modulator array, may be replaced with spacers. In other devices, particular organic materials may be used in spacers on support structures to increase the reliability of these spacers.

Particular implementations of the subject matter described in this disclosure can be implemented to realize one or more of the following potential advantages. By replacing blue interferometric modulator elements with spacer structures, spacers may be dispersed throughout an array of interferometric modulators while having a minimal effect on the brightness of the interferometric modulator display, since the blue pixels contribute less brightness to the display than red or green pixels. The fabrication of these “blue-pixel” support structures can be integrated into the manufacturing process of the display through the deposition of a single additional layer, as existing layers can be used to form part of the “blue-pixel” spacer. Similarly, by using overlying organic spacers on top of support structures or other structures, more reliable and resilient spacers can be provided. The implementation of spacers can prevent or reduce the damage to the interferometric modulators arising from contact with packaging. In some implementations, spacers enable the use of devices having thinner packaging than can be used for devices that are manufactured without spacers.

An example of a suitable EMS or MEMS device or apparatus, to which the described implementations may apply, is a reflective display device. Reflective display devices can incorporate interferometric modulator (IMOD) display elements that can be implemented to selectively absorb and/or reflect light incident thereon using principles of optical interference. IMOD display elements can include a partial optical absorber, a reflector that is movable with respect to the absorber, and an optical resonant cavity defined between the absorber and the reflector. In some implementations, the reflector can be moved to two or more different positions, which can change the size of the optical resonant cavity and thereby affect the reflectance of the IMOD. The reflectance spectra of IMOD display elements can create fairly broad spectral bands that can be shifted across the visible wavelengths to generate different colors. The position of the spectral band can be adjusted by changing the thickness of the optical resonant cavity. One way of changing the optical resonant cavity is by changing the position of the reflector with respect to the absorber.

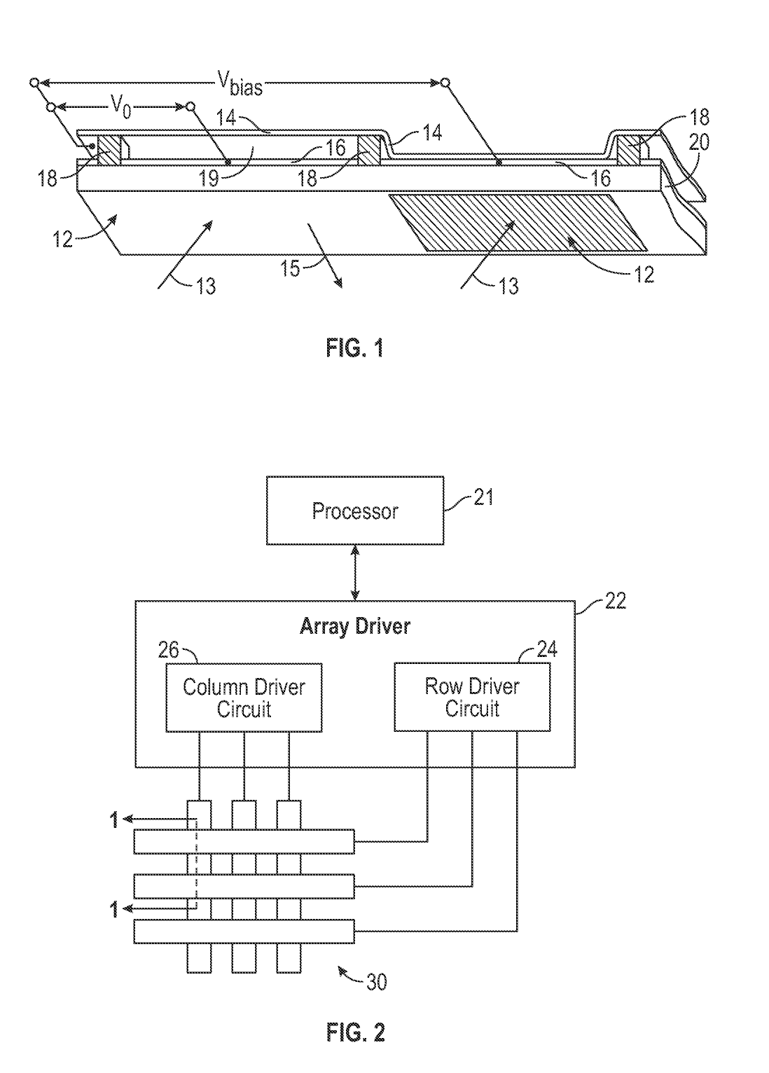

FIG. 1 is an isometric view illustration depicting two adjacent interferometric modulator (IMOD) display elements in a series or array of display elements of an IMOD display device. The IMOD display device includes one or more interferometric EMS, such as MEMS, display elements. In these devices, the interferometric MEMS display elements can be configured in either a bright or dark state. In the bright (“relaxed,” “open” or “on,” etc.) state, the display element reflects a large portion of incident visible light. Conversely, in the dark (“actuated,” “closed” or “off,” etc.) state, the display element reflects little incident visible light. MEMS display elements can be configured to reflect predominantly at particular wavelengths of light allowing for a color display in addition to black and white. In some implementations, by using multiple display elements, different intensities of color primaries and shades of gray can be achieved.

The IMOD display device can include an array of IMOD display elements which may be arranged in rows and columns. Each display element in the array can include at least a pair of reflective and semi-reflective layers, such as a movable reflective layer (i.e., a movable layer, also referred to as a mechanical layer) and a fixed partially reflective layer (i.e., a stationary layer), positioned at a variable and controllable distance from each other to form an air gap (also referred to as an optical gap, cavity or optical resonant cavity). The movable reflective layer may be moved between at least two positions. For example, in a first position, i.e., a relaxed position, the movable reflective layer can be positioned at a distance from the fixed partially reflective layer. In a second position, i.e., an actuated position, the movable reflective layer can be positioned more closely to the partially reflective layer. Incident light that reflects from the two layers can interfere constructively and/or destructively depending on the position of the movable reflective layer and the wavelength(s) of the incident light, producing either an overall reflective or non-reflective state for each display element. In some implementations, the display element may be in a reflective state when unactuated, reflecting light within the visible spectrum, and may be in a dark state when actuated, absorbing and/or destructively interfering light within the visible range. In some other implementations, however, an IMOD display element may be in a dark state when unactuated, and in a reflective state when actuated. In some implementations, the introduction of an applied voltage can drive the display elements to change states. In some other implementations, an applied charge can drive the display elements to change states.

The depicted portion of the array in FIG. 1 includes two adjacent interferometric MEMS display elements in the form of IMOD display elements 12. In the display element 12 on the right (as illustrated), the movable reflective layer 14 is illustrated in an actuated position near, adjacent or touching the optical stack 16. The voltage V_{bias} applied across the display element 12 on the right is sufficient to move and also maintain the movable reflective layer 14 in the actuated position. In the display element 12 on the left (as illustrated), a movable reflective layer 14 is illustrated in a relaxed position at a distance (which may be predetermined based on design parameters) from an optical stack 16, which includes a partially reflective layer. The voltage V₀ applied across the display element 12 on the left is insufficient to cause actuation of the movable reflective layer 14 to an actuated position such as that of the display element 12 on the right.

In FIG. 1, the reflective properties of IMOD display elements 12 are generally illustrated with arrows indicating light 13 incident upon the IMOD display elements 12, and light 15 reflecting from the display element 12 on the left. Most of the light 13 incident upon the display elements 12 may be transmitted through the transparent substrate 20, toward the optical stack 16. A portion of the light incident upon the optical stack 16 may be transmitted through the partially reflective layer of the optical stack 16, and a portion will be reflected back through the transparent substrate 20. The portion of light 13 that is transmitted through the optical stack 16 may be reflected from the movable reflective layer 14, back toward (and through) the transparent substrate 20. Interference (constructive and/or destructive) between the light reflected from the partially reflective layer of the optical stack 16 and the light reflected from the movable reflective layer 14 will determine in part the intensity of wavelength(s) of light 15 reflected from the display element 12 on the viewing or substrate side of the device. In some implementations, the transparent substrate 20 can be a glass substrate (sometimes referred to as a glass plate or panel). The glass substrate may be or include, for example, a borosilicate glass, a soda lime glass, quartz, Pyrex, or other suitable glass material. In some implementations, the glass substrate may have a thickness of 0.3, 0.5 or 0.7 millimeters, although in some implementations the glass substrate can be thicker (such as tens of millimeters) or thinner (such as less than 0.3 millimeters). In some implementations, a non-glass substrate can be used, such as a polycarbonate, acrylic, polyethylene terephthalate (PET) or polyether ether ketone (PEEK) substrate. In such an implementation, the non-glass substrate will likely have a thickness of less than 0.7 millimeters, although the substrate may be thicker depending on the design considerations. In some implementations, a non-transparent substrate, such as a metal foil or stainless steel-based substrate can be used. For example, a reverse-IMOD-based display, which includes a fixed reflective layer and a movable layer which is partially transmissive and partially reflective, may be configured to be viewed from the opposite side of a substrate as the display elements 12 of FIG. 1 and may be supported by a non-transparent substrate.

The optical stack 16 can include a single layer or several layers. The layer(s) can include one or more of an electrode layer, a partially reflective and partially transmissive layer, and a transparent dielectric layer. In some implementations, the optical stack 16 is electrically conductive, partially transparent and partially reflective, and may be fabricated, for example, by depositing one or more of the above layers onto a transparent substrate 20. The electrode layer can be formed from a variety of materials, such as various metals, for example indium tin oxide (ITO). The partially reflective layer can be formed from a variety of materials that are partially reflective, such as various metals (e.g., chromium and/or molybdenum), semiconductors, and dielectrics. The partially reflective layer can be formed of one or more layers of materials, and each of the layers can be formed of a single material or a combination of materials. In some implementations, certain portions of the optical stack 16 can include a single semi-transparent thickness of metal or semiconductor which serves as both a partial optical absorber and electrical conductor, while different, electrically more conductive layers or portions (e.g., of the optical stack 16 or of other structures of the display element) can serve to bus signals between IMOD display elements. The optical stack 16 also can include one or more insulating or dielectric layers covering one or more conductive layers or an electrically conductive/partially absorptive layer.

In some implementations, at least some of the layer(s) of the optical stack 16 can be patterned into parallel strips, and may form row electrodes in a display device as described further below. As will be understood by one having ordinary skill in the art, the term “patterned” is used herein to refer to masking as well as etching processes. In some implementations, a highly conductive and reflective material, such as aluminum (Al), may be used for the movable reflective layer 14, and these strips may form column electrodes in a display device. The movable reflective layer 14 may be formed as a series of parallel strips of a deposited metal layer or layers (orthogonal to the row electrodes of the optical stack 16) to form columns deposited on top of supports, such as the illustrated posts 18, and an intervening sacrificial material located between the posts 18. When the sacrificial material is etched away, a defined gap 19, or optical cavity, can be formed between the movable reflective layer 14 and the optical stack 16. In some implementations, the spacing between posts 18 may be approximately 1-1000 μm, while the gap 19 may be approximately less than 10,000 Angstroms (Å).

In some implementations, each IMOD display element, whether in the actuated or relaxed state, can be considered as a capacitor formed by the fixed and moving reflective layers. When no voltage is applied, the movable reflective layer 14 remains in a mechanically relaxed state, as illustrated by the display element 12 on the left in FIG. 1, with the gap 19 between the movable reflective layer 14 and optical stack 16. However, when a potential difference, i.e., a voltage, is applied to at least one of a selected row and column, the capacitor formed at the intersection of the row and column electrodes at the corresponding display element becomes charged, and electrostatic forces pull the electrodes together. If the applied voltage exceeds a threshold, the movable reflective layer 14 can deform and move near or against the optical stack 16. A dielectric layer (not shown) within the optical stack 16 may prevent shorting and control the separation distance between the layers 14 and 16, as illustrated by the actuated display element 12 on the right in FIG. 1. The behavior can be the same regardless of the polarity of the applied potential difference. Though a series of display elements in an array may be referred to in some instances as “rows” or “columns,” a person having ordinary skill in the art will readily understand that referring to one direction as a “row” and another as a “column” is arbitrary. Restated, in some orientations, the rows can be considered columns, and the columns considered to be rows. In some implementations, the rows may be referred to as “common” lines and the columns may be referred to as “segment” lines, or vice versa. Furthermore, the display elements may be evenly arranged in orthogonal rows and columns (an “array”), or arranged in non-linear configurations, for example, having certain positional offsets with respect to one another (a “mosaic”). The terms “array” and “mosaic” may refer to either configuration. Thus, although the display is referred to as including an “array” or “mosaic,” the elements themselves need not be arranged orthogonally to one another, or disposed in an even distribution, in any instance, but may include arrangements having asymmetric shapes and unevenly distributed elements.

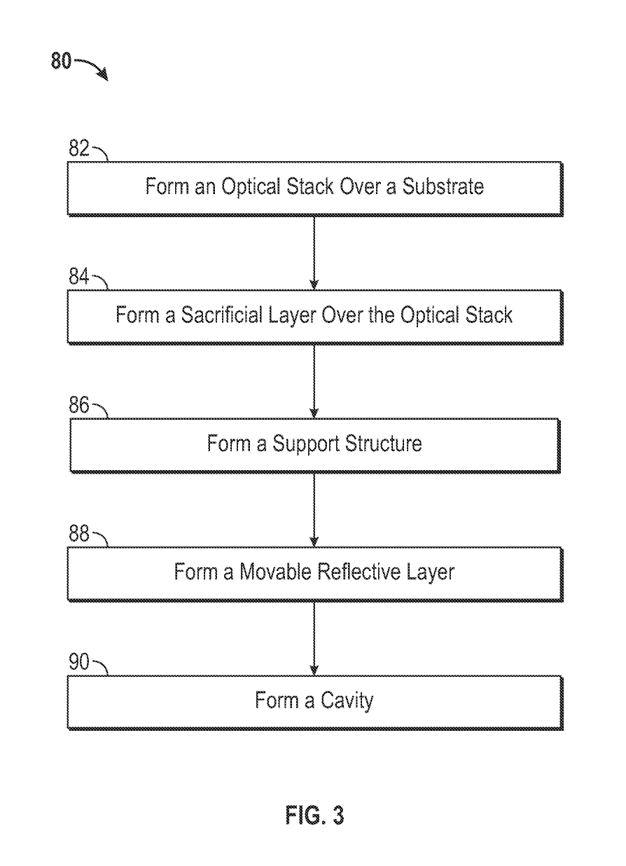

FIG. 2 is a system block diagram illustrating an electronic device incorporating an IMOD-based display including a three element by three element array of IMOD display elements. The electronic device includes a processor 21 that may be configured to execute one or more software modules. In addition to executing an operating system, the processor 21 may be configured to execute one or more software applications, including a web browser, a telephone application, an email program, or any other software application.

The processor 21 can be configured to communicate with an array driver 22. The array driver 22 can include a row driver circuit 24 and a column driver circuit 26 that provide signals to, for example a display array or panel 30. The cross section of the IMOD display device illustrated in FIG. 1 is shown by the lines 1-1 in FIG. 2. Although FIG. 2 illustrates a 3×3 array of IMOD display elements for the sake of clarity, the display array 30 may contain a very large number of IMOD display elements, and may have a different number of IMOD display elements in rows than in columns, and vice versa.

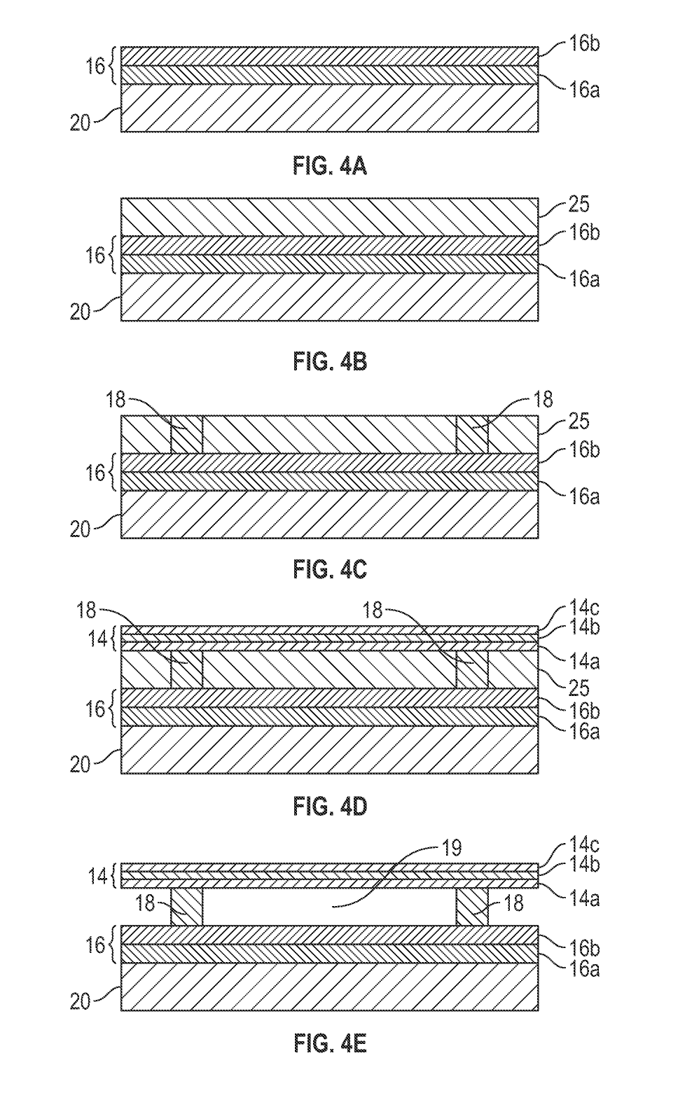

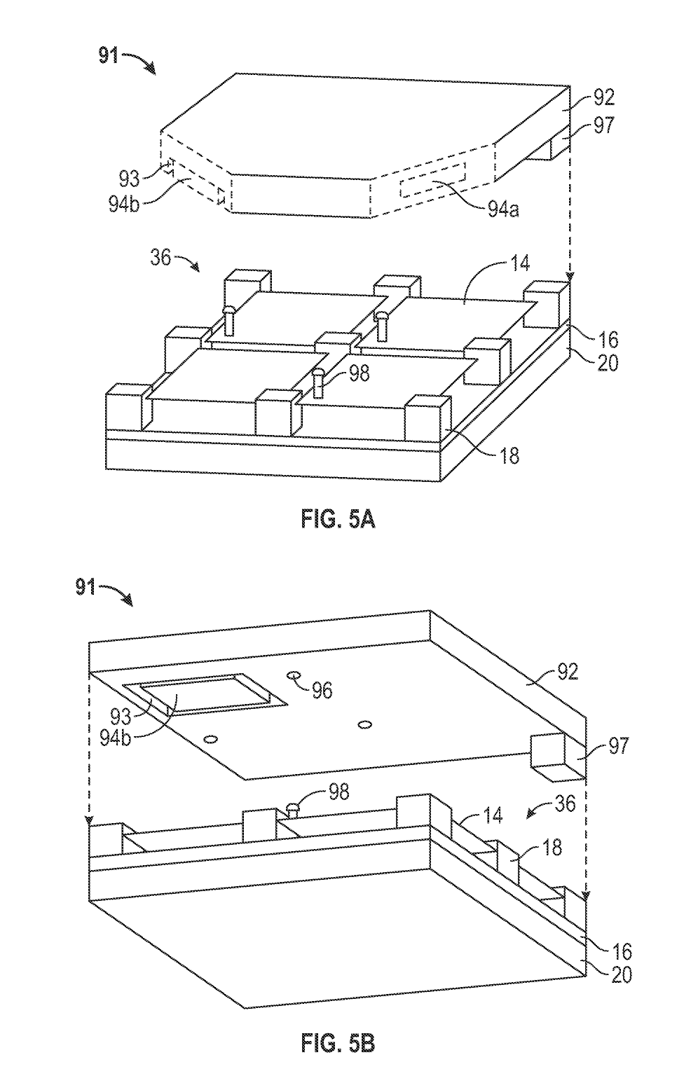

FIG. 3 is a flow diagram illustrating a manufacturing process 80 for an IMOD display or display element. FIGS. 4A-4E are cross-sectional illustrations of various stages in the manufacturing process 80 for making an IMOD display or display element. In some implementations, the manufacturing process 80 can be implemented to manufacture one or more EMS devices, such as IMOD displays or display elements. The manufacture of such an EMS device also can include other blocks not shown in FIG. 3. The process 80 begins at block 82 with the formation of the optical stack 16 over the substrate 20. FIG. 4A illustrates such an optical stack 16 formed over the substrate 20. The substrate 20 may be a transparent substrate such as glass or plastic such as the materials discussed above with respect to FIG. 1. The substrate 20 may be flexible or relatively stiff and unbending, and may have been subjected to prior preparation processes, such as cleaning, to facilitate efficient formation of the optical stack 16. As discussed above, the optical stack 16 can be electrically conductive, partially transparent, partially reflective, and partially absorptive, and may be fabricated, for example, by depositing one or more layers having the desired properties onto the transparent substrate 20.

In FIG. 4A, the optical stack 16 includes a multilayer structure having sub-layers 16a and 16b, although more or fewer sub-layers may be included in some other implementations. In some implementations, one of the sub-layers 16a and 16b can be configured with both optically absorptive and electrically conductive properties, such as the combined conductor/absorber sub-layer 16a. In some implementations, one of the sub-layers 16a and 16b can include molybdenum-chromium (molychrome or MoCr), or other materials with a suitable complex refractive index. Additionally, one or more of the sub-layers 16a and 16b can be patterned into parallel strips, and may form row electrodes in a display device. Such patterning can be performed by a masking and etching process or another suitable process known in the art. In some implementations, one of the sub-layers 16a and 16b can be an insulating or dielectric layer, such as an upper sub-layer 16b that is deposited over one or more underlying metal and/or oxide layers (such as one or more reflective and/or conductive layers). In addition, the optical stack 16 can be patterned into individual and parallel strips that form the rows of the display. In some implementations, at least one of the sub-layers of the optical stack, such as the optically absorptive layer, may be quite thin (e.g., relative to other layers depicted in this disclosure), even though the sub-layers 16a and 16b are shown somewhat thick in FIGS. 4A-4E.

The process 80 continues at block 84 with the formation of a sacrificial layer 25 over the optical stack 16. Because the sacrificial layer 25 is later removed (see block 90) to form the cavity 19, the sacrificial layer 25 is not shown in the resulting IMOD display elements. FIG. 4B illustrates a partially fabricated device including a sacrificial layer 25 formed over the optical stack 16. The formation of the sacrificial layer 25 over the optical stack 16 may include deposition of a xenon difluoride (XeF₂)-etchable material such as molybdenum (Mo) or amorphous silicon (Si), in a thickness selected to provide, after subsequent removal, a gap or cavity 19 (see also FIG. 4E) having a desired design size. Deposition of the sacrificial material may be carried out using deposition techniques such as physical vapor deposition (PVD, which includes many different techniques, such as sputtering), plasma-enhanced chemical vapor deposition (PECVD), thermal chemical vapor deposition (thermal CVD), or spin-coating.

The process 80 continues at block 86 with the formation of a support structure such as a support post 18. The formation of the support post 18 may include patterning the sacrificial layer 25 to form a support structure aperture, then depositing a material (such as a polymer or an inorganic material, like silicon oxide) into the aperture to form the support post 18, using a deposition method such as PVD, PECVD, thermal CVD, or spin-coating. In some implementations, the support structure aperture formed in the sacrificial layer can extend through both the sacrificial layer 25 and the optical stack 16 to the underlying substrate 20, so that the lower end of the support post 18 contacts the substrate 20. Alternatively, as depicted in FIG. 4C, the aperture formed in the sacrificial layer 25 can extend through the sacrificial layer 25, but not through the optical stack 16. For example, FIG. 4E illustrates the lower ends of the support posts 18 in contact with an upper surface of the optical stack 16. The support post 18, or other support structures, may be formed by depositing a layer of support structure material over the sacrificial layer 25 and patterning portions of the support structure material located away from apertures in the sacrificial layer 25. The support structures may be located within the apertures, as illustrated in FIG. 4C, but also can extend at least partially over a portion of the sacrificial layer 25. As noted above, the patterning of the sacrificial layer 25 and/or the support posts 18 can be performed by a masking and etching process, but also may be performed by alternative patterning methods.

The process 80 continues at block 88 with the formation of a movable reflective layer or membrane such as the movable reflective layer 14 illustrated in FIG. 4D. The movable reflective layer 14 may be formed by employing one or more deposition steps, including, for example, reflective layer (such as aluminum, aluminum alloy, or other reflective materials) deposition, along with one or more patterning, masking and/or etching steps. The movable reflective layer 14 can be patterned into individual and parallel strips that form, for example, the columns of the display. The movable reflective layer 14 can be electrically conductive, and referred to as an electrically conductive layer. In some implementations, the movable reflective layer 14 may include a plurality of sub-layers 14a, 14b and 14c as shown in FIG. 4D. In some implementations, one or more of the sub-layers, such as sub-layers 14a and 14c, may include highly reflective sub-layers selected for their optical properties, and another sub-layer 14b may include a mechanical sub-layer selected for its mechanical properties. In some implementations, the mechanical sub-layer may include a dielectric material. Since the sacrificial layer 25 is still present in the partially fabricated IMOD display element formed at block 88, the movable reflective layer 14 is typically not movable at this stage. A partially fabricated IMOD display element that contains a sacrificial layer 25 also may be referred to herein as an “unreleased” IMOD.

The process 80 continues at block 90 with the formation of a cavity 19. The cavity 19 may be formed by exposing the sacrificial material 25 (deposited at block 84) to an etchant. For example, an etchable sacrificial material such as Mo or amorphous Si may be removed by dry chemical etching by exposing the sacrificial layer 25 to a gaseous or vaporous etchant, such as vapors derived from solid XeF₂ for a period of time that is effective to remove the desired amount of material. The sacrificial material is typically selectively removed relative to the structures surrounding the cavity 19. Other etching methods, such as wet etching and/or plasma etching, also may be used. Since the sacrificial layer 25 is removed during block 90, the movable reflective layer 14 is typically movable after this stage. After removal of the sacrificial material 25, the resulting fully or partially fabricated IMOD display element may be referred to herein as a “released” IMOD.

In some implementations, the packaging of an EMS component or device, such as an IMOD-based display, can include a backplate (alternatively referred to as a backplane, back glass or recessed glass) which can be configured to protect the EMS components from damage (such as from mechanical interference or potentially damaging substances). The backplate also can provide structural support for a wide range of components, including but not limited to driver circuitry, processors, memory, interconnect arrays, vapor barriers, product housing, and the like. In some implementations, the use of a backplate can facilitate integration of components and thereby reduce the volume, weight, and/or manufacturing costs of a portable electronic device.

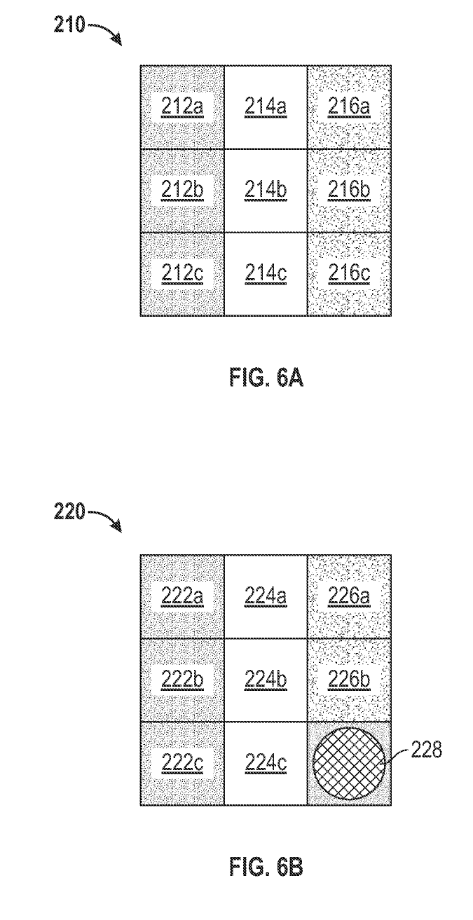

FIGS. 5A and 5B are schematic exploded partial perspective views of a portion of an EMS package 91 including an array 36 of EMS elements and a backplate 92. FIG. 5A is shown with two corners of the backplate 92 cut away to better illustrate certain portions of the backplate 92, while FIG. 5B is shown without the corners cut away. The EMS array 36 can include a substrate 20, support posts 18, and a movable layer 14. In some implementations, the EMS array 36 can include an array of IMOD display elements with one or more optical stack portions 16 on a transparent substrate, and the movable layer 14 can be implemented as a movable reflective layer.

The backplate 92 can be essentially planar or can have at least one contoured surface (e.g., the backplate 92 can be formed with recesses and/or protrusions). The backplate 92 may be made of any suitable material, whether transparent or opaque, conductive or insulating. Suitable materials for the backplate 92 include, but are not limited to, glass, plastic, ceramics, polymers, laminates, metals, metal foils, Kovar and plated Kovar.

As shown in FIGS. 5A and 5B, the backplate 92 can include one or more backplate components 94a and 94b, which can be partially or wholly embedded in the backplate 92. As can be seen in FIG. 5A, backplate component 94a is embedded in the backplate 92. As can be seen in FIGS. 5A and 5B, backplate component 94b is disposed within a recess 93 formed in a surface of the backplate 92. In some implementations, the backplate components 94a and/or 94b can protrude from a surface of the backplate 92. Although backplate component 94b is disposed on the side of the backplate 92 facing the substrate 20, in other implementations, the backplate components can be disposed on the opposite side of the backplate 92.

The backplate components 94a and/or 94b can include one or more active or passive electrical components, such as transistors, capacitors, inductors, resistors, diodes, switches, and/or integrated circuits (ICs) such as a packaged, standard or discrete IC. Other examples of backplate components that can be used in various implementations include antennas, batteries, and sensors such as electrical, touch, optical, or chemical sensors, or thin-film deposited devices.

In some implementations, the backplate components 94a and/or 94b can be in electrical communication with portions of the EMS array 36. Conductive structures such as traces, bumps, posts, or vias may be formed on one or both of the backplate 92 or the substrate 20 and may contact one another or other conductive components to form electrical connections between the EMS array 36 and the backplate components 94a and/or 94b. For example, FIG. 5B includes one or more conductive vias 96 on the backplate 92 which can be aligned with electrical contacts 98 extending upward from the movable layers 14 within the EMS array 36. In some implementations, the backplate 92 also can include one or more insulating layers that electrically insulate the backplate components 94a and/or 94b from other components of the EMS array 36. In some implementations in which the backplate 92 is formed from vapor-permeable materials, an interior surface of backplate 92 can be coated with a vapor barrier (not shown).

The backplate components 94a and 94b can include one or more desiccants which act to absorb any moisture that may enter the EMS package 91. In some implementations, a desiccant (or other moisture absorbing materials, such as a getter) may be provided separately from any other backplate components, for example as a sheet that is mounted to the backplate 92 (or in a recess formed therein) with adhesive. Alternatively, the desiccant may be integrated into the backplate 92. In some other implementations, the desiccant may be applied directly or indirectly over other backplate components, for example by spray-coating, screen printing, or any other suitable method.

In some implementations, the EMS array 36 and/or the backplate 92 can include mechanical standoffs 97 to maintain a distance between the backplate components and the display elements and thereby prevent mechanical interference between those components. In the implementation illustrated in FIGS. 5A and 5B, the mechanical standoffs 97 are formed as posts protruding from the backplate 92 in alignment with the support posts 18 of the EMS array 36. Alternatively or in addition, mechanical standoffs, such as rails or posts, can be provided along the edges of the EMS package 91.

Although not illustrated in FIGS. 5A and 5B, a seal can be provided which partially or completely encircles the EMS array 36. Together with the backplate 92 and the substrate 20, the seal can form a protective cavity enclosing the EMS array 36. The seal may be a semi-hermetic seal, such as a conventional epoxy-based adhesive. In some other implementations, the seal may be a hermetic seal, such as a thin film metal weld or a glass frit. In some other implementations, the seal may include polyisobutylene (PIB), polyurethane, liquid spin-on glass, solder, polymers, plastics, or other materials. In some implementations, a reinforced sealant can be used to form mechanical standoffs.

In alternate implementations, a seal ring may include an extension of either one or both of the backplate 92 or the substrate 20. For example, the seal ring may include a mechanical extension (not shown) of the backplate 92. In some implementations, the seal ring may include a separate member, such as an O-ring or other annular member.

In some implementations, the EMS array 36 and the backplate 92 are separately formed before being attached or coupled together. For example, the edge of the substrate 20 can be attached and sealed to the edge of the backplate 92 as discussed above. Alternatively, the EMS array 36 and the backplate 92 can be formed and joined together as the EMS package 91. In some other implementations, the EMS package 91 can be fabricated in any other suitable manner, such as by forming components of the backplate 92 over the EMS array 36 by deposition.

The interferometric modulators described above have been described as bi-stable elements having a relaxed state and an actuated state. The above and following description, however, also may be used with analog interferometric modulators having a range of states. For example, an analog interferometric modulator can have a red state, a green state, a blue state, a black state and a white state in addition to other color states. Accordingly, a single interferometric modulator can be configured to have various states with different light reflectance properties over a wide range of the optical spectrum.

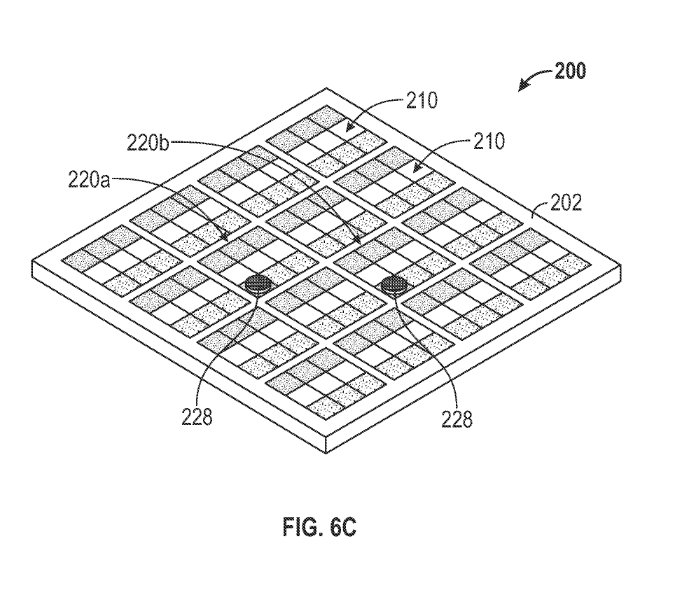

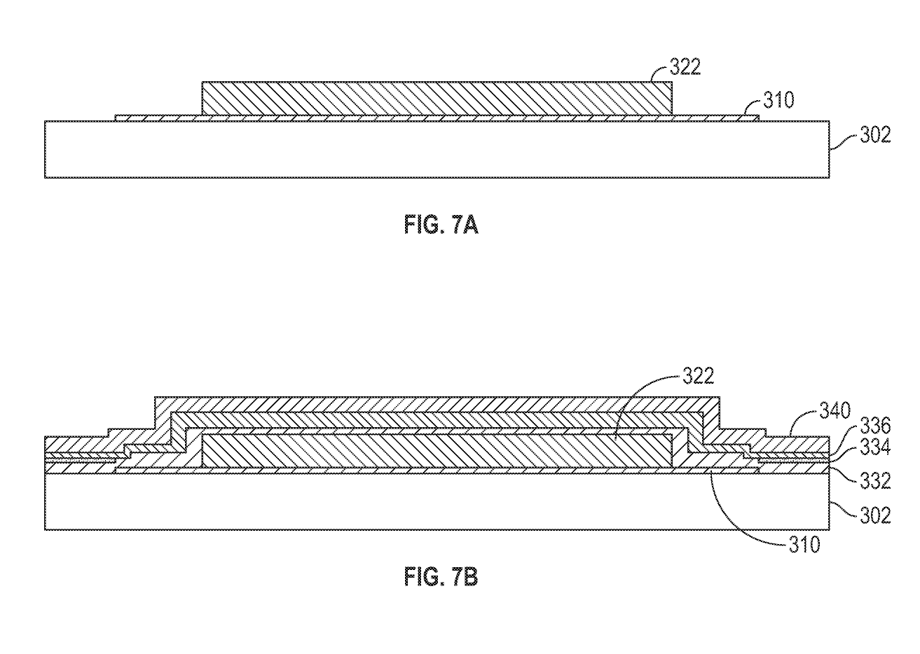

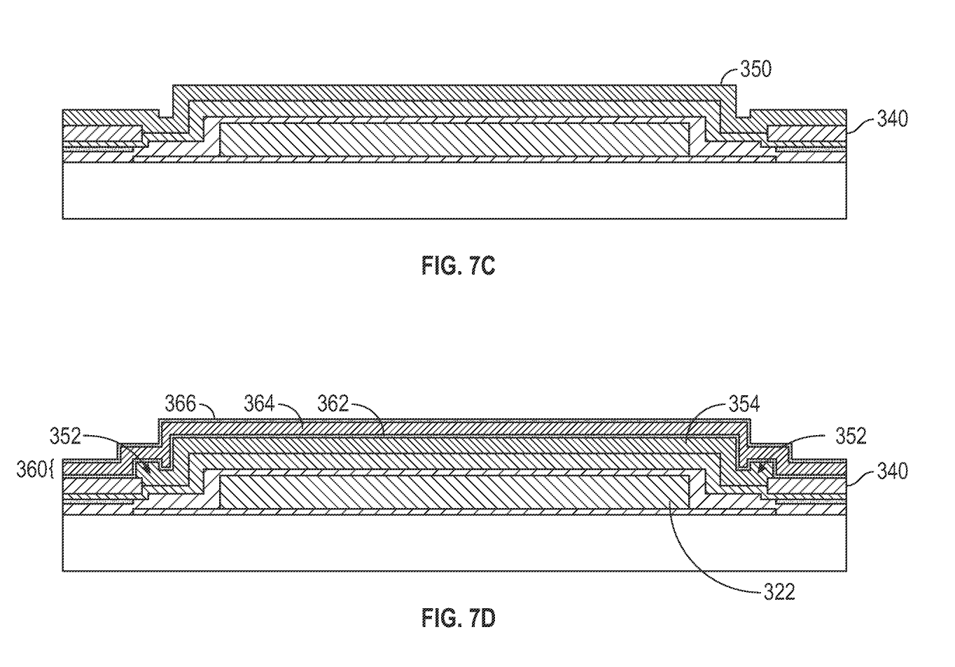

FIG. 6A shows an example of a schematic illustration of an interferometric modulator pixel. In the illustrated implementation, the pixel 210 includes nine total subpixels arranged in a 3×3 array. Pixel 210 includes three subpixels 212a, 212b and 212c configured to reflect red light, three subpixels 214a, 214b and 214c configured to reflect green light, and three subpixels 216a, 216b and 216c configured to reflect blue light. To facilitate driving of the pixel, the subpixels of the same color are arranged in a column, although any other arrangement of subpixels is possible. Similarly, pixels including more or less than nine subpixels may be used, and such pixels may include subpixels configured to reflect more or less than three total colors of light. Similarly, while the terms “pixel” and “subpixel” are used herein for convenience, the implementations discussed herein may be applied to non-optical devices, or to devices in which elements are arranged in other groupings.

FIG. 6B shows an example of a schematic illustration of an interferometric modulator pixel in which one of the subpixels has been replaced with a spacer structure. The pixel 220 includes eight total subpixels and one spacer structure arranged in a 3×3 array. Pixel 220 includes three subpixels 222a, 222b and 222c configured to reflect red light, three subpixels 224a, 224b and 224c configured to reflect green light, two subpixels 226a and 226b configured to reflect blue light, and a spacer structure 228 which takes the place of the third blue subpixel 216c of pixel 210 of FIG. 6A.

FIG. 6C is a perspective view schematically illustrating an array of interferometric modulators disposed on a substrate. The array 200 of interferometric modulators disposed on a substrate 202 includes 16 different pixels. Pixels 210 are 3×3 arrays of subpixels including three subpixels of each of red, green, and blue, such as the pixels 210 of FIG. 6A. Pixels 220a and 220b are arrays including eight total subpixels and one spacer structure 228 arranged in a 3×3 array, such as the pixels 220 of FIG. 6B. As schematically illustrated in FIG. 6C, the height of the spacer structure 228 is higher than the height of the surrounding subpixels. A typical difference in height between the spacer structures 228 and the surrounding array is larger than 0.5 um, although the height differential in a particular implementation may depend on a variety of factors, including the number of spacer structures 228 within the array 200 and the spacing therebetween, as an increased height differential may be used to account for a lower density of spacer structures 228 within the array 200.

In some other implementations, the number of pixels within an array may be larger or smaller than the 16 pixels shown in the implementation of FIG. 6C, and in many implementations the number of pixels may be significantly larger. The relative density of “spacer pixels” such as pixels 220a and 220b, in which a subpixel is replaced with a spacer structure, also may be greater or less than in array 200 of FIG. 6C and the distribution of such spacer pixels may be regular or may be arranged in an irregular pattern. For example, the number of spacer pixels may be increased near the center of the display to account for an increased flexure of an overlying backplate near a center of the backplate.

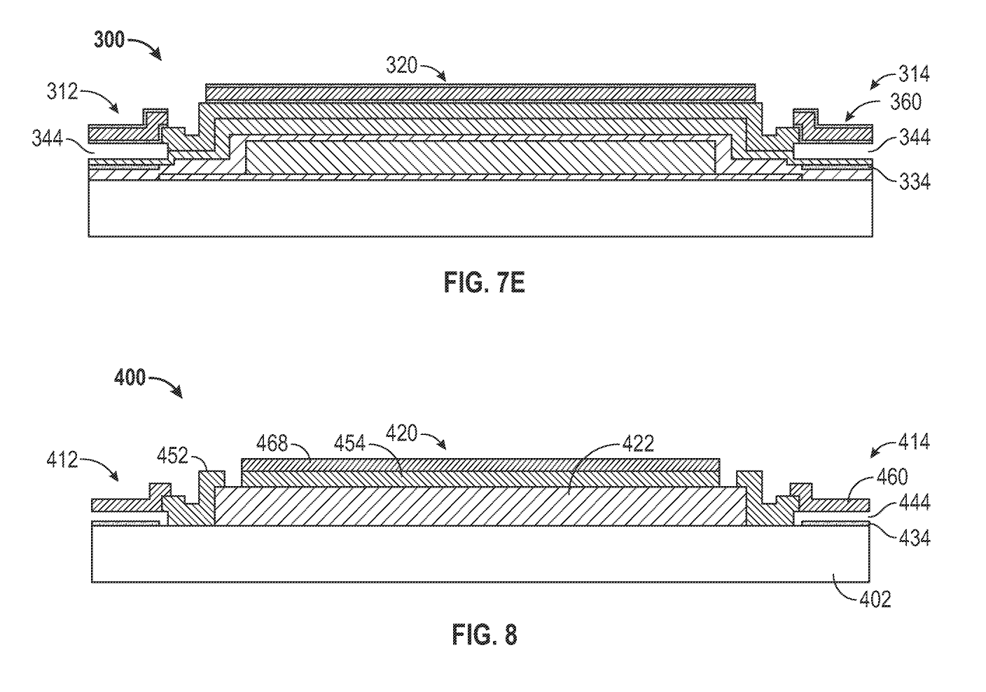

FIGS. 7A-7E show an example of a fabrication process which can be used to form a spacer structure within an array of interferometric modulators. In FIG. 7A, one or more layers are deposited on a substrate 302 and patterned to form a masking structure referred to as a dark mask 310. A layer of spacer material has also been deposited and patterned to form a spacer layer 322. In the illustrated implementation, the dark mask 310 underlies the spacer layer 322 and extends laterally outward beyond the spacer layer 322. Because portions of the resultant interferometric modulator array will be optically inactive, the dark mask 310 shields these structures from view, preventing or minimizing the undesirable optical effects that could result from reflection of light off of the undersides of structures within optically inactive areas, such as spacer layers 322 and support structures.

In one implementation, the dark mask 310 can be a black etalon, formed by depositing an absorber layer, a spacer layer, and a reflective layer, and patterning the three layers to form a stack of layers that reflects little or no visible light due to destructive interference between light reflected by the absorber layer and light passing through the absorber layer and reflected back through the absorber layer by the reflective layer. With proper selection of materials and thicknesses, a dark or black etalon can be formed. Such a dark or black etalon may alternately be referred to herein as an interferometric black mask.

The spacer layer 322 can be formed from a wide variety of suitable materials. In some implementations, the spacer layer 322 may be formed from a material used to form other materials in the display, in order to minimize the number of different materials used in the overall fabrication process. The material of the spacer material may be selectively etchable relative to the upper layer of the dark mask 310. The thickness of the spacer structure may be selected such that the overall height of the resultant structure will be sufficiently taller than the surrounding portions of the array to protect the remainder of the array from mechanical interference. As discussed above, the particular height differential sufficient to provide this protection will depend on the spacing between spacer structures within the resultant array. The spacer layer 322 or similar structures described throughout the specification thus provide means for raising the height of overlying layers such as portions of a movable layer or portions of a layer of support material, although other layers also may overlie the spacer layer 322 in addition to or in place of these layers in other implementations.

In some implementations, the dark mask 310 may be formed by depositing and patterning on or more layers prior to the deposition of the material which will form spacer layer 322. In other implementations, the materials forming the dark mask 310 and the spacer layer 322 are deposited before the dark mask 310 is patterned, and the spacer layer 322 may be patterned before the dark mask 310 is patterned.

In FIG. 7B, a buffer layer 332 is deposited over the dark mask 310 and spacer layer 322 to insulate conductive material within the dark mask 310 from other structures. A conductive layer is deposited and patterned to form electrodes 334, and a dielectric layer 336 has been deposited over the electrodes 334 to electrically isolate the electrodes 334 from overlying conductive layers. Although in the illustrated implementation, the conductive layer which forms electrodes 334 has been removed from the area overlying spacer layer 322, the conductive layer may in other implementations remain over all or part of the spacer layer 322. Finally, a sacrificial layer 340 is deposited over the dielectric layer 336.

In the illustrated implementation of a fabrication process for interferometric modulators, the conductive layer is a conductive absorber layer, and the electrode 334 serves as an optical absorber in addition to an electrode. In other implementations, however, where non-optical EMS devices are being fabricated, the conductive layer may only serve as an electrode, and the optical properties of the conductive layer may not be important to the operation of the EMS device.

In FIG. 7C, the sacrificial layer 340 is patterned to form apertures by removing portions of the sacrificial layer corresponding to locations where support structures will subsequently be formed. In addition, a support layer 350 has been deposited over the patterned sacrificial layer 340. In some implementations, the support layer 350 includes an oxide such as silicon oxide (SiO2), although a wide variety of suitable materials also may be used.

In some implementations, where the interferometric modulator array will include three different cavity sizes corresponding to interferometric modulators configured to reflect different colors, the sacrificial layer 340 may be a multilayer structure, formed by sequentially depositing and patterning three different sacrificial sublayers such that the sacrificial layer 340 has at least three different thicknesses across the sacrificial layer 340.

In FIG. 7D, the support layer 350 has been patterned to form support posts 352, but in the areas overlying the spacer layer 322, a portion 354 of the support layer 350 (see FIG. 7C) remains and extends between two adjacent support posts. A movable layer 360 has also been deposited over the post structure, including a lower reflective layer 362, a mechanical layer 364, and a top layer 366. Like the sacrificial layer 340, the mechanical layer 364 may in some implementations be a multilayer structure, with three mechanical sublayers being sequentially deposited and patterned to form a mechanical layer 364 which has at least three different thicknesses across the mechanical layer 364. The top layer 366 may in some implementations include the same or similar material and thickness as the lower reflective layer 362 such that residual stress or thermal expansion/contraction of the lower reflective layer 362 will be balanced by the same in the top layer 366, preventing undesirable flexure of the movable layer 360. While the movable layer 360 is not movable at the time of deposition, subsequent removal of the sacrificial layer discussed in greater detail below will permit the portions of the movable layer 360 extending between support structures 352 to be electrostatically deflected by the underlying electrode 334.

In FIG. 7E, the movable layer 360 is patterned to form strip electrodes and the sacrificial layer 340 (see FIG. 7D) is removed to form a cavity 344 between portions of the movable layer 360 and the electrodes 334. An array 300 of interferometric modulators is thus formed, in which spacer structures 320 are located between interferometric modulator elements 312 and 314. The height of the spacer structures 320 is at least 0.5 um greater than the height of the surrounding interferometric modulator elements 312 and 314 due to the height of the spacer layer 322 within the spacer structure 320. In addition, because the sacrificial layer 340 overlying spacer structure 320 was removed, no cavity is formed within the spacer structure 320 by the release etch, and the spacer structure is a continuous structure, providing additional stability.

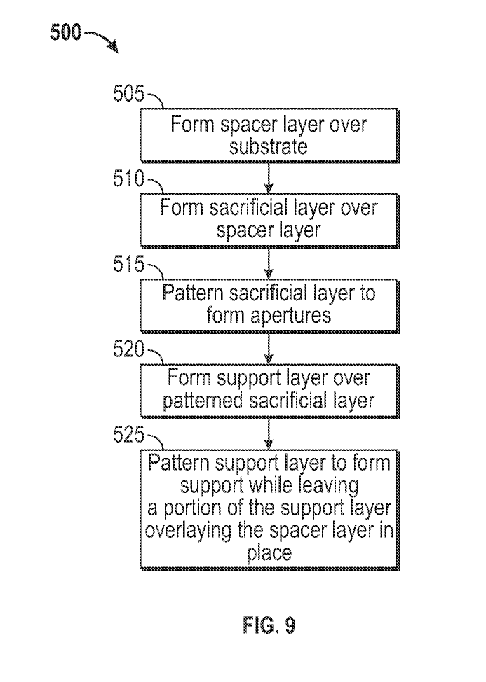

FIG. 8 shows an example of a cross-section of another implementation of spacer structure within an array of interferometric modulators. The array 400 of FIG. 8 includes a spacer structure 420 disposed between EMS devices 412 and 414. The EMS devices 412 and 414 include a conductive layer 434 supported by substrate 402 and spaced apart from an overlying movable layer 460 by a cavity 444. The movable layer 460 is supported by support structures 452.

The spacer structure 420 includes a spacer layer 422 overlying the substrate 402. Overlying the spacer layer 422 are a layer 454 which includes the same material as the support posts 452, and a layer 468 which includes the same material as the movable layer 460. As can be seen in FIG. 8, these layers 454 and 468 may be formed simultaneously with the support posts 452 and the movable layer 460 respectively, and may be formed by not removing the portions of the layers used to form the support posts 452 and the movable layer 460 which overlie the spacer layer 422.

While the array 400 illustrated in FIG. 8 includes certain array elements, other implementations of an array such as array 400 may include additional array elements not described above with respect to FIG. 8. For example, a dark mask such as an interferometric black mask may be disposed between the substrate and the support posts and/or spacer element 420. Similarly, whether or not described above with respect to FIG. 8, array elements may include properties different from or in addition to those described above. For example, conductive layer 434 may be formed from an appropriate thickness of an appropriate material to function as an optical absorber. Similarly, a lower layer of a multilayer movable layer 460 may be reflective.

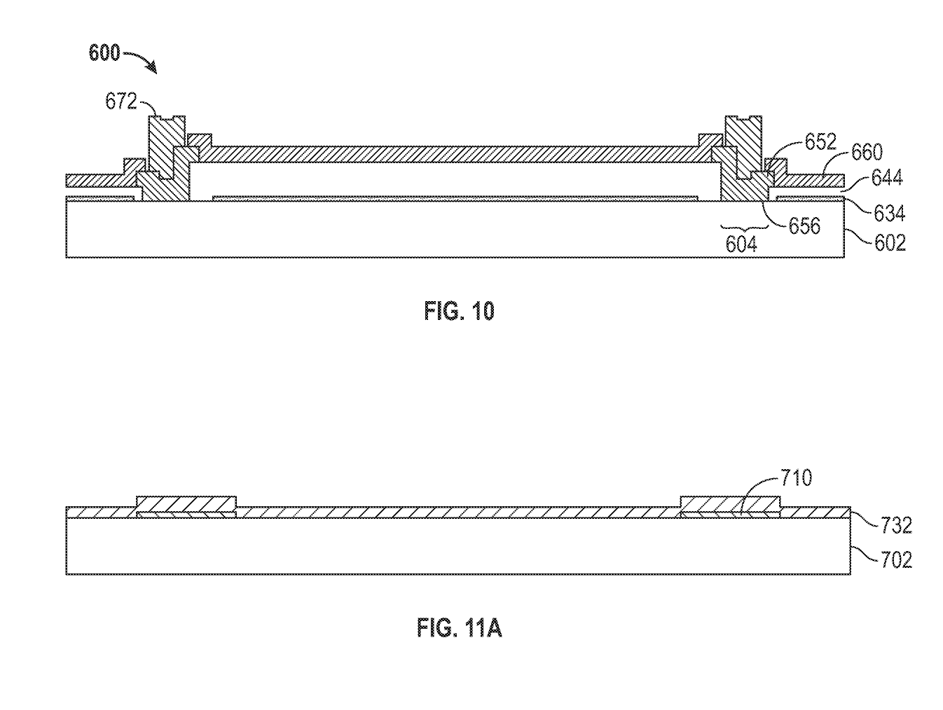

FIG. 9 shows an example of a block diagram illustrating a method of fabricating an array of interferometric modulators including at least one spacer structure disposed within the array. The method 500 begins at a block 505 where a spacer layer is formed over a substrate. The method also may include the formation of a dark mask or other masking structure underneath the sacrificial layer.

The method 500 then moves to a block 510 where a sacrificial layer is formed over the spacer layer. In some implementations, additional layers, such as buffer layers and conductive layers are formed after forming the spacer layer in block 505 and before forming the sacrificial layer in block 510.

The method 500 then moves to a block 515, where the sacrificial layer is patterned to form a plurality of apertures, where at least one of the apertures extends over the spacer layer. Additional apertures may extend over additional spacer layers, or may be formed where support posts will eventually be formed. In addition, support posts may be formed at the edges of apertures extending over spacer layers.

The method 500 then moves to a block 520 where a support layer is formed over the patterned sacrificial layer. The support layer may be formed from any suitable material, and may make contact with a layer underlying the sacrificial layer at the base of the apertures formed in the sacrificial layer.

The method 500 finally moves to a block 525 where the support layer is patterned to form support structures, but a portion of the support layer overlying the spacer layer remains in place. By leaving the portion of the support layer overlying the spacer layer in place, the height of a spacer structure including the spacer layer will be increased. While the block 525 is illustrated as the final block in the method 500, other implementations of methods of fabrication may include additional steps performed before or after step 525. For example, a movable layer may be formed after the support structures are formed, as discussed above, and a portion of the movably layer overlying the spacer layer may be left in place. Similarly, the sacrificial layer may be removed in a subsequent step via a release etch. Additional steps discussed elsewhere in the specification and not specifically discussed with respect to method 500 also may be incorporated into other implementations, along with at least some of the steps of method 500.

As discussed above with respect to FIG. 6C, the density of spacer structures which replace subpixels or other EMS elements may vary, and represents a balance between the effect on the performance of the array of EMS devices and the amount of protection afforded to the array by the inclusion of such spacer structures. In one particular implementation, one out of every 16 pixels includes a region in which a subpixel is replaced by a spacer structure. For 3×3 RGB pixels which otherwise include nine subpixels—three each of red, green and blue—the replacement of one of the subpixels with a spacer structure will mean that one out of every 48 subpixels of that color within 16-pixel region will be replaced with a masked structure.

The contribution of a given subpixel to the overall brightness of a pixel depends heavily on the color which that subpixel is configured to reflect. While a green subpixel contributes roughly 16% of the brightness to a pixel with nine subpixels, and a red subpixel contributes roughly 6% of the brightness, a blue subpixel may only contribute roughly 3%-6% of the brightness to a pixel. When one out of every 16 pixels includes one spacer structure replacing a blue subpixel, the net effect on the overall brightness of the display is roughly 0.1%. Thus, for an RGB array of interferometric modulators, replacement of blue subpixels will have less of an effect on the overall brightness of a display than replacement of other subpixels of other colors.

Nevertheless, in other implementations, subpixels which are red or green may be replaced by spacer structures, in addition to or instead of replacement of blue subpixels. Similarly, as discussed above, other implementations of interferometric modulators may include multi-state or analog interferometric modulators, and an appropriate selection of such a subpixel for replacement with a spacer structure may be made, taking into account the overall effect on the brightness and appearance of the resulting display.

Similarly, while implementations discussed above mention the replacement of one or two subpixels in each group of 16 pixels, other implementations may include replacement of larger or smaller amounts of subpixels. The overall height of the spacer structure also may be used to compensate for decreased spacer density. In some implementations, these spacer structures may be distributed throughout the array in a regular pattern, while in other implementations, a random or pseudo-random distribution of spacer structures may be used. In addition, the density of these spacer structures may in some implementations be greater near the center of the array where flexure of an overlying backplate is expected to be the greatest.

In other implementations, rather than replacing an optically active component of an array of interferometric modulators, spacer structures can be located within optically inactive areas of the array, such as the areas in which support structures are located. In particular, these spacer structures may overlie the support post, such that no additional active area is sacrificed due to its inclusion.

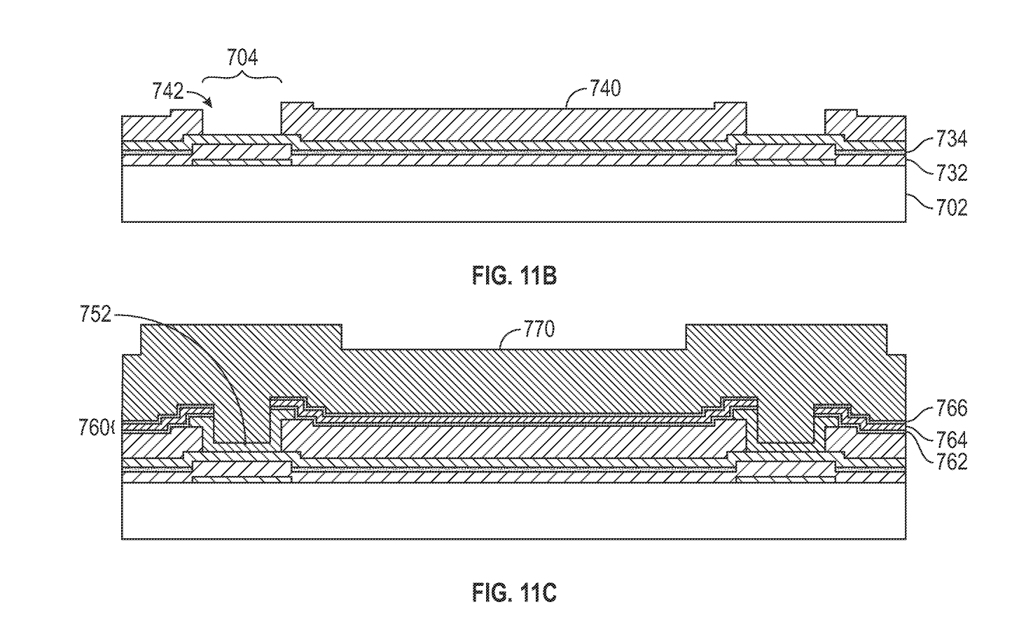

FIG. 10 shows an example of a cross-section of a portion of an array of interferometric modulators in which a spacer structure overlies a portion of a support structure. The array 600 includes a conductive layer 634 located over a substrate 602, and a movable layer 660 spaced apart from the conductive layer 634 and supported by support structures 652 on the opposite side of a cavity 644. The support structures 652 include a base portion 656 in contact with an underlying layer—in this case the substrate 602—at anchor location 604.

Overlying the support structure 652 is a spacer structure 672, which has a base having a width less than the width of the base portion 656 of the support structure 652, such that the base of the spacer structure does not extend beyond the edges of anchor location 604 of the layer underlying the support structure 652. Because of this constraint on the cross-sectional dimensions of the spacer structure 672, no portion of the base of spacer structure 672 overlies a portion of cavity 644, and a load on the spacers from contact with a backplate can be borne by a contiguous layer stack underlying the spacer structure 672. In contrast, if spacer structure 672 were to extend over a portion of the cavity 644, the mechanical layer 660 or outwardly extending wings of support structure 652 could be forced downward, increasing the chances of mechanical failure of the spacer structure 672 and damage to sensitive portions of the array 600. In some implementations, the spacer structure 672 may have a width which is greater at point on the spacer structure 672 some distance above the base without necessarily forcing a cantilevered portion of support structure 652 downward in response to application of a force on the spacer structure 672.

In some implementations, the spacer structure 672 can be formed from a layer of organic material, and in particular from a layer of cross-linked organic material. The use of cross-linked organic material has been shown to provide more durable spacer structures which are less likely to fail under load than spacer structures formed from other materials. Suitable organic material can be identified based at least in part on some or all of the following properties: elastic modulus, recovery rate after deformation, resistance to chemical attack (such as a xenon difluoride etch which can be used to remove a sacrificial layer), outgassing properties and sidewall profile after patterning. Some examples of suitable organic materials are: the HDM-41xx series of materials sold by HD Micro Systems™ and JSR NN856 sold by JSR Micro, although a wide variety of other organic materials also may be used to form the spacer structure 672.

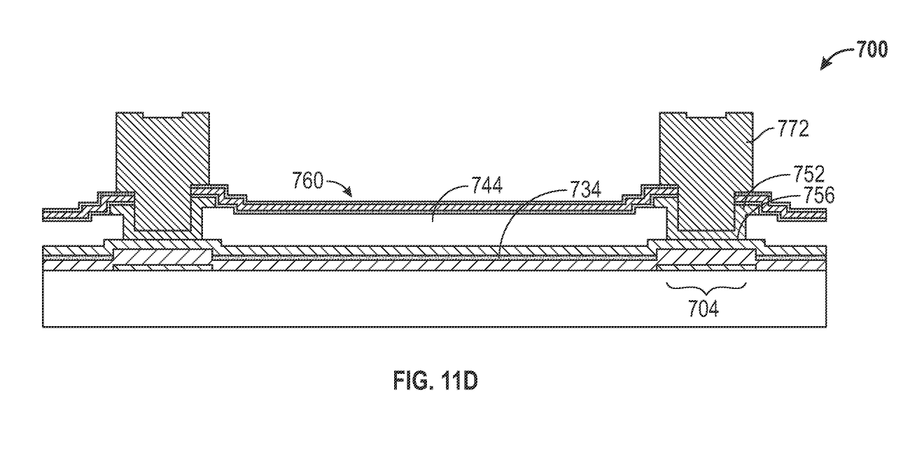

FIGS. 11A-11D show an example of a fabrication process which can be used to form an overlying spacer structure within an array of interferometric modulators. In FIG. 11A, a dark mask 710 is formed over a substrate 702 via a process similar to that described with respect to dark mask 310 of FIG. 7A. A buffer layer 732 is also formed over the dark mask 710. Because the spacer structure formed by this process will not be positioned between support structures, as with the spacer structure 320 of FIG. 7E, the dark mask 710 does not need to extend into portions of the array that would otherwise be optically active, and may underlie only the support structures and other optically inactive components such as bussing layers.

In FIG. 11B, a conductive layer 734 is formed over the buffer layer 732, and a dielectric layer 736 is formed over the conductive layer 734 and buffer layer 732. A sacrificial layer 740 is deposited and patterned to form apertures 742, which correspond to the eventual location of support structures. The apertures 742 expose a portion of an underlying layer—the dielectric layer 736 in the illustrated implementation—and this exposed portion of the underlying layer will serve as an anchor location 704 for the eventual support structure.

In FIG. 11C, a layer of support material has been deposited and patterned to form support structures 752, and a movable layer 760 has been formed over the support structures 752. In the illustrated implementation, the movable layer 760 includes a lower reflective layer 762, a mechanical layer 764, and a top layer 766, similar to the movable layer 360 of FIG. 7D. A layer 770 of spacer material is formed over the patterned movable layer 760. Because a portion of the movable layer 760 may be removed such that a single support structure 752 supports two (or more) electrically and physically isolated portions of movable layer 760, the movable layer 760 in the illustrated implementation is patterned prior to deposition of the spacer layer 770.

Finally, in FIG. 11D, the layer 770 (see FIG. 11C) of spacer material is patterned to form spacer structures 772 overlying the support structures 752, and having a base which does not extend outside of the anchor location 704 underlying the base 756 of the support structure 752. The sacrificial layer 740 (see FIG. 11C) is also removed to form cavities 744 between the movable layer 760 and the conductive layer 734 in the finished array 700.

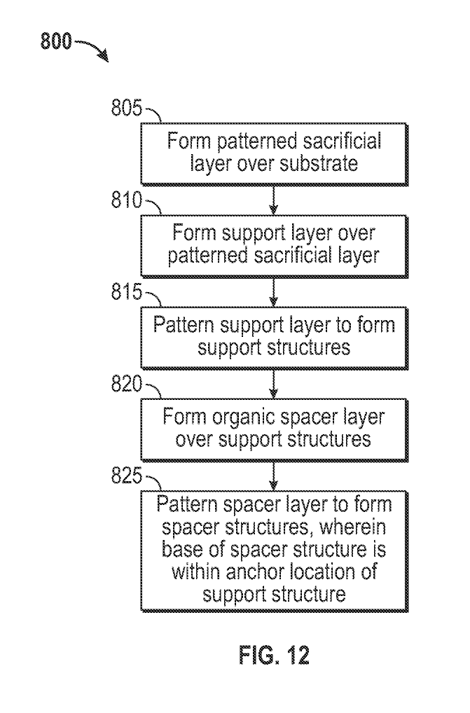

FIG. 12 shows an example of a block diagram illustrating a method of fabricating an array of interferometric modulators including at least one spacer overlying a support structure. The method 800 begins at a block 805 where a patterned sacrificial layer is formed over a substrate, by forming a sacrificial layer over the substrate and patterning the sacrificial layer to form apertures therein. Additional layers, such as conductive layers and dark or black masks may be formed over the substrate prior to forming the patterned sacrificial layer.

The method 800 moves to a block 810, where a support layer is formed over the patterned sacrificial layer. The support layer may be formed from any suitable material and may contact with an underlying layer at anchor locations.

The method 800 moves to a block 815, where the support layer is patterned to form support structures. As discussed above, these support structures may have a base which is in contact with an underlying layer at an anchor location. The support structures may, for example, also include an outwardly extending wing portion which extends over a portion of the sacrificial layer.

The method 800 moves to a block 820, where a spacer layer is formed over the support structures. As discussed above, additional layers or structures may be formed after forming the support structures and prior to forming a spacer layer over the support structures. For example, a movable layer, which may include a mechanical layer and one or more additional reflective or metal layers, may be formed and patterned after forming the support posts, such that the movable layer will be supported by the support posts. As discussed above, the spacer layer may be an organic material, and may in particular be a cross-linked organic material.

Finally, the method 800 moves to a block 825 where the spacer layer is patterned to form spacer structures. The spacer structures have a base having a dimension which is within the anchor location at the base of the support structures, such that the base of the spacer will not overlie a portion of the sacrificial layer. Even when the sacrificial layer is subsequently removed, the base of the spacer structure will overlie only solid layers, and will not overlie a portion of a cavity formed by removal of the sacrificial layer.

In some implementations, overlying spacer structures may be used in conjunction with spacer structures which replace subpixels or other EMS device elements. For example, an overlying spacer structure may be disposed over any portion of an interferometric modulator array sufficiently rigid to provide support for the same. In particular, an overlying spacer structure may be disposed over a spacer structure which replaces a subpixel, so as to further increase the height of the overall spacer structure.

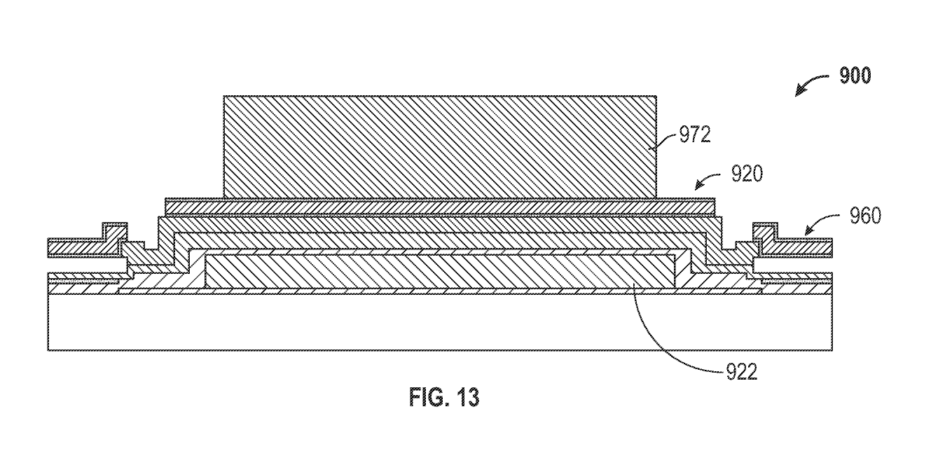

FIG. 13 shows an example of an interferometric modulator array which includes both a spacer structure which replaces a subpixel of the array and an additional spacer structure overlying the subpixel-replacing spacer structure. In particular, the array 900 includes a spacer structure 920 formed from an underlying spacer layer 922 and a stack of other materials used in the fabrication of the interferometric modulator array. Overlying the spacer 920 is an additional spacer structure 972, which may be formed from any suitable material. In some implementations, the spacer structure 972 may include an organic material, such as those described above with respect to FIG. 10. Because the underlying spacer structure 920 supporting the spacer structure 972 is a solid stack of layers, additional support may be provided to the spacer structure 972, increasing the load which the spacer structure 972 can bear before failing and providing additional protection to the array. In the illustrated implementation, the spacer structure 972 does not extend outside the edges of the underlying spacer layer 922, but in other implementations the spacer structure can be narrower or wider than depicted in FIG. 13. In some implementations, the spacer structure 972 can be built on the other layers within spacer structure 920, such as movable layer 960 and layer 950 of support material, without forming an underlying spacer layer 922. In some implementations, the spacer structure 972 can be built much taller than the spacer structure 772 (see FIG. 11D), because the underlying structure 920 in the space between support structure locations provides a much wider base for building the spacer structure 972 than the support structures 752.

Fabrication of such an array may proceed as described with respect to FIGS. 7A-7D. However, after patterning the movable layer 960, a layer of spacer material may be deposited and patterned to form spacer structures 972 in a desired shape. This deposition and patterning to form spacer structures 972 may in some implementations be similar to the process described with respect to FIGS. 11C-11D, although other suitable deposition and patterning processes may also be used.

While the above figures schematically illustrate certain implementations of interferometric modulator devices or methods for fabricating arrays of interferometric modulators, the above teachings can be applied to other EMS devices, whether optical or non-optical. Similarly, other implementations may include additional or fewer components or steps than those discussed above. Both the illustrated steps and additional steps not specifically illustrated or discussed herein may be used to form additional structures not specifically depicted herein. For example, certain of the layers discussed herein may additionally be patterned to form vias between conductive layers which allow for electrical routing throughout the array of interferometric modulators. Additional bussing structures may similarly be formed within and about the array.

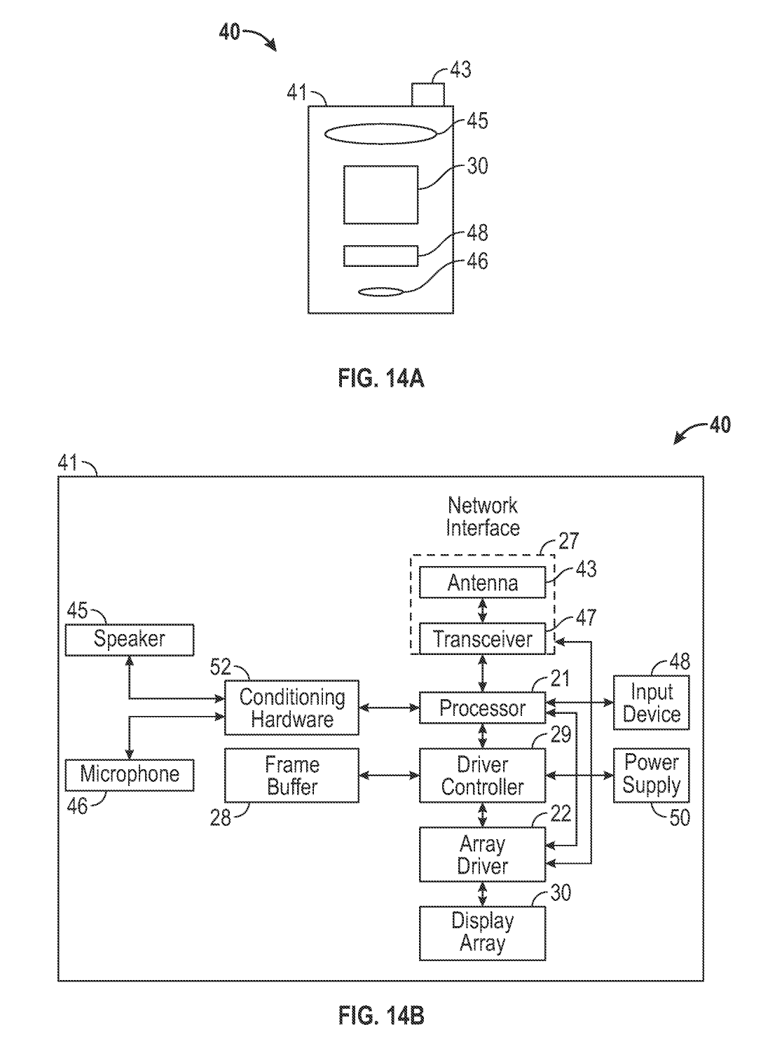

FIGS. 14A and 14B are system block diagrams illustrating a display device 40 that includes a plurality of IMOD display elements. The display device 40 can be, for example, a smart phone, a cellular or mobile telephone. However, the same components of the display device 40 or slight variations thereof are also illustrative of various types of display devices such as televisions, computers, tablets, e-readers, hand-held devices and portable media devices.

The display device 40 includes a housing 41, a display 30, an antenna 43, a speaker 45, an input device 48 and a microphone 46. The housing 41 can be formed from any of a variety of manufacturing processes, including injection molding, and vacuum forming. In addition, the housing 41 may be made from any of a variety of materials, including, but not limited to: plastic, metal, glass, rubber and ceramic, or a combination thereof. The housing 41 can include removable portions (not shown) that may be interchanged with other removable portions of different color, or containing different logos, pictures, or symbols.

The display 30 may be any of a variety of displays, including a bi-stable or analog display, as described herein. The display 30 also can be configured to include a flat-panel display, such as plasma, EL, OLED, STN LCD, or TFT LCD, or a non-flat-panel display, such as a CRT or other tube device. In addition, the display 30 can include an IMOD-based display, as described herein.

The components of the display device 40 are schematically illustrated in FIG. 14A. The display device 40 includes a housing 41 and can include additional components at least partially enclosed therein. For example, the display device 40 includes a network interface 27 that includes an antenna 43 which can be coupled to a transceiver 47. The network interface 27 may be a source for image data that could be displayed on the display device 40. Accordingly, the network interface 27 is one example of an image source module, but the processor 21 and the input device 48 also may serve as an image source module. The transceiver 47 is connected to a processor 21, which is connected to conditioning hardware 52. The conditioning hardware 52 may be configured to condition a signal (such as filter or otherwise manipulate a signal). The conditioning hardware 52 can be connected to a speaker 45 and a microphone 46. The processor 21 also can be connected to an input device 48 and a driver controller 29. The driver controller 29 can be coupled to a frame buffer 28, and to an array driver 22, which in turn can be coupled to a display array 30. One or more elements in the display device 40, including elements not specifically depicted in FIG. 14A, can be configured to function as a memory device and be configured to communicate with the processor 21. In some implementations, a power supply 50 can provide power to substantially all components in the particular display device 40 design.

The network interface 27 includes the antenna 43 and the transceiver 47 so that the display device 40 can communicate with one or more devices over a network. The network interface 27 also may have some processing capabilities to relieve, for example, data processing requirements of the processor 21. The antenna 43 can transmit and receive signals. In some implementations, the antenna 43 transmits and receives RF signals according to the IEEE 16.11 standard, including IEEE 16.11(a), (b), or (g), or the IEEE 802.11 standard, including IEEE 802.11a, b, g, n, and further implementations thereof. In some other implementations, the antenna 43 transmits and receives RF signals according to the Bluetooth® standard. In the case of a cellular telephone, the antenna 43 can be designed to receive code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), 1xEV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless network, such as a system utilizing 3G, 4G or 5G technology. The transceiver 47 can pre-process the signals received from the antenna 43 so that they may be received by and further manipulated by the processor 21. The transceiver 47 also can process signals received from the processor 21 so that they may be transmitted from the display device 40 via the antenna 43.

In some implementations, the transceiver 47 can be replaced by a receiver. In addition, in some implementations, the network interface 27 can be replaced by an image source, which can store or generate image data to be sent to the processor 21. The processor 21 can control the overall operation of the display device 40. The processor 21 receives data, such as compressed image data from the network interface 27 or an image source, and processes the data into raw image data or into a format that can be readily processed into raw image data. The processor 21 can send the processed data to the driver controller 29 or to the frame buffer 28 for storage. Raw data typically refers to the information that identifies the image characteristics at each location within an image. For example, such image characteristics can include color, saturation and gray-scale level.

The processor 21 can include a microcontroller, CPU, or logic unit to control operation of the display device 40. The conditioning hardware 52 may include amplifiers and filters for transmitting signals to the speaker 45, and for receiving signals from the microphone 46. The conditioning hardware 52 may be discrete components within the display device 40, or may be incorporated within the processor 21 or other components.

The driver controller 29 can take the raw image data generated by the processor 21 either directly from the processor 21 or from the frame buffer 28 and can re-format the raw image data appropriately for high speed transmission to the array driver 22. In some implementations, the driver controller 29 can re-format the raw image data into a data flow having a raster-like format, such that it has a time order suitable for scanning across the display array 30. Then the driver controller 29 sends the formatted information to the array driver 22. Although a driver controller 29, such as an LCD controller, is often associated with the system processor 21 as a stand-alone Integrated Circuit (IC), such controllers may be implemented in many ways. For example, controllers may be embedded in the processor 21 as hardware, embedded in the processor 21 as software, or fully integrated in hardware with the array driver 22.

The array driver 22 can receive the formatted information from the driver controller 29 and can re-format the video data into a parallel set of waveforms that are applied many times per second to the hundreds, and sometimes thousands (or more), of leads coming from the display's x-y matrix of display elements.

In some implementations, the driver controller 29, the array driver 22, and the display array 30 are appropriate for any of the types of displays described herein. For example, the driver controller 29 can be a conventional display controller or a bi-stable display controller (such as an IMOD display element controller). Additionally, the array driver 22 can be a conventional driver or a bi-stable display driver (such as an IMOD display element driver). Moreover, the display array 30 can be a conventional display array or a bi-stable display array (such as a display including an array of IMOD display elements). In some implementations, the driver controller 29 can be integrated with the array driver 22. Such an implementation can be useful in highly integrated systems, for example, mobile phones, portable-electronic devices, watches or small-area displays.

In some implementations, the input device 48 can be configured to allow, for example, a user to control the operation of the display device 40. The input device 48 can include a keypad, such as a QWERTY keyboard or a telephone keypad, a button, a switch, a rocker, a touch-sensitive screen, a touch-sensitive screen integrated with the display array 30, or a pressure- or heat-sensitive membrane. The microphone 46 can be configured as an input device for the display device 40. In some implementations, voice commands through the microphone 46 can be used for controlling operations of the display device 40.

The power supply 50 can include a variety of energy storage devices. For example, the power supply 50 can be a rechargeable battery, such as a nickel-cadmium battery or a lithium-ion battery. In implementations using a rechargeable battery, the rechargeable battery may be chargeable using power coming from, for example, a wall socket or a photovoltaic device or array. Alternatively, the rechargeable battery can be wirelessly chargeable. The power supply 50 also can be a renewable energy source, a capacitor, or a solar cell, including a plastic solar cell or solar-cell paint. The power supply 50 also can be configured to receive power from a wall outlet.

In some implementations, control programmability resides in the driver controller 29 which can be located in several places in the electronic display system. In some other implementations, control programmability resides in the array driver 22. The above-described optimization may be implemented in any number of hardware and/or software components and in various configurations.

As used herein, a phrase referring to “at least one of a list of items refers to any combination of those items, including single members. As an example, “at least one of: a, b, or c” is intended to cover: a, b, c, a-b, a-c, b-c, and a-b-c.

The various illustrative logics, logical blocks, modules, circuits and algorithm steps described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and steps described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor also may be implemented as a combination of computing devices, such as a combination of a DSP and a microprocessor, a plurality of microprocessors, one or more microprocessors in conjunction with a DSP core, or any other such configuration. In some implementations, particular steps and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein. Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of, e.g., an IMOD display element as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, a person having ordinary skill in the art will readily recognize that such operations need not be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. A device, comprising:
a conductive layer supported by an underlying substrate;
a movable layer overlying at least a portion of the conductive layer;
a plurality of support structures underlying at least a portion of the movable layer and spacing the movable layer apart from the conductive layer by a cavity, wherein the plurality of post structures are anchored to an underlying layer at anchor locations; and
a spacer layer disposed in an area between anchor locations, wherein the spacer structure underlies a first layer including the same material as the support structures and a second layer including the same material as the movable layer, wherein the upper surface of the second layer overlying the spacer layer is located at a greater height from the surface of the substrate than the remainder of the device.

2. The device of claim 1, wherein the conductive layer is a conductive absorber layer.

3. The device of claim 1, additionally including a masking structure extending underneath at least the anchor locations and the spacer layer.

4. The device of claim 3, wherein the masking structure includes an interferometric black mask.

5. The device of claim 1, wherein the first layer extends between at least a first anchor location and a second anchor location.

6. The device of claim 5, wherein the first layer extends between four adjacent anchor locations.

7. The device of claim 1, additionally including an additional spacer structure overlying a portion of the device, wherein the additional spacer structure includes an organic material.

8. The device of claim 7, wherein the additional spacer structure overlies a support structure, and wherein the additional spacer structure does not extend outward beyond the edges of the anchor location underlying the support structure.

9. The device of claim 7, wherein the additional spacer structure overlies the spacer layer, and wherein the additional spacer structure does not extend outward beyond the edges of the spacer layer.

10. The device of claim 1, additionally including:
a processor that is configured to communicate with at least one of the conductive layer and mechanical layer, the processor being configured to process image data; and
a memory device that is configured to communicate with the processor.

11. The device of claim 10, additionally including:
a driver circuit configured to send at least one signal to at least one of the conductive layer and mechanical layer; and
a controller configured to send at least a portion of the image data to the driver circuit.

12. The device of claim 10, additionally including an image source module configured to send the image data to the processor, wherein the image source module includes at least one of a receiver, transceiver, and transmitter.

13. The device of claim 10, additionally including an input device configured to receive input data and to communicate the input data to the processor.

14. A device, comprising:
an array of interferometric modulators (IMODs) arranged as a plurality of pixels, wherein the array includes:
a first portion of the array defining a first pixel, the first pixel including a plurality of IMODs configured to reflect light of a first color, and a plurality of IMODs configured to reflect light of a second color; and
a second portion of the array defining a second pixel, wherein the second portion of the array is substantially similar in size to the first portion of the array, the second pixel including at least one less IMOD configured to reflect light of a first color than the first pixel, wherein the second pixel further includes a spacer disposed within the second portion of the array, and wherein the spacer extends to a height higher than the remainder of the second pixel.

15. The device of claim 14, wherein the first color of light is blue and the second color of light is red, wherein the first pixel further includes a plurality of IMODs configured to reflect green light.

16. The device of claim 14, additionally comprising an interferometric black mask underlying at least a portion of the spacer.

17. The device of claim 14, wherein the spacer comprises an oxide.

18. A method of fabricating a device, comprising:
forming at least one spacer over a substrate;
forming a sacrificial layer over the spacer;
patterning the sacrificial layer to include a plurality of apertures, wherein at least one of the plurality of apertures extends over the spacer;
forming a support layer over the patterned sacrificial layer; and
patterning the support layer to form support structures, wherein a portion of the support layer overlying the spacer remains in place.

19. The method of claim 18, additionally including:
forming a movable layer after patterning the support layer to form support structures; and
patterning the movable layer, wherein a portion of the movable layer overlying the spacer remains in place.

20. The method of claim 18, additionally including forming a conductive layer over the substrate prior to forming the sacrificial layer.

21. The method of claim 20, additionally forming a buffer layer over at least the conductive layer and the spacer.

22. The method of claim 20, additionally forming an interferometric black mask over the substrate, wherein the interferometric black mask is formed over the masking structure.

23. A device, comprising:
a conductive layer supported by an underlying substrate;
a movable layer overlying at least a portion of the conductive layer;
a plurality of support structures underlying at least a portion of the movable layer and spacing the movable layer apart from the conductive layer by a cavity, wherein the plurality of post structures are anchored to an underlying layer at anchor locations; and
means for raising the height of overlying layers, wherein the raising means underlies a first layer including the same material as the support structures and a second layer including the same material as the mechanical layer, wherein the upper surface of the second layer overlying the raising means is located at a greater height from the surface of the substrate than the remainder of the device.

24. The device of claim 23, wherein the raising means include a spacer layer disposed in an area between anchor locations.

25. A device, comprising:
a conductive layer supported by an underlying substrate;
a movable layer overlying at least a portion of the conductive layer;
a plurality of support structures underlying at least a portion of the mechanical layer and spacing the movable layer apart from the conductive layer by a cavity, wherein the plurality of post structures are anchored to an underlying layer at anchor locations; and
a spacer overlying at least one support structure, wherein the spacer includes an organic material, and wherein a base of the spacer does not extend outward beyond the edges of the anchor location underlying the support structure.

26. The device of claim 25, wherein the spacer comprises a cross-linked organic material.

27. The device of claim 25, wherein the conductive layer comprises an optical absorber, and wherein at least a portion of the movable layer adjacent the cavity comprises a reflective material.
